(19) United States
(12) Patent Application Publication
(10) Pub. No.: US 2026/0082991 A1
(43) Pub. Date: Mar. 19, 2026

(54) SEMICONDUCTOR DEVICE

(71) Applicants: KABUSHIKI KAISHA TOSHIBA, Tokyo (JP); Toshiba Electronic Devices & Storage Corporation, Tokyo (JP)

(72) Inventors: Taira TABAKOYA, Chiba Chiba (JP); Eitaro MIYAKE, Tachikawa Tokyo (JP)

(73) Assignees: KABUSHIKI KAISHA TOSHIBA, Tokyo (JP); Toshiba Electronic Devices & Storage Corporation, Tokyo (JP)

(21) Appl. No.: 19/246,813

(22) Filed: Jun. 24, 2025

(30) Foreign Application Priority Data
Sep. 17, 2024 (JP) 2024-160083

(51) Int. Cl. H01L 23/24; H01L 23/00; H01L 23/31; H01L 25/07; H05K 1/02; H05K 1/14; H05K 1/18; H10D 80/20

(52) U.S. Cl. CPC H10W 76/47; H05K 1/0298; H05K 1/144; H05K 1/181; H10W 74/114; H10W 90/00; H10D 80/20; H10D 80/251; H10W 72/865; H10W 72/884; H10W 90/734; H10W 90/736; H10W 90/754

(57) ABSTRACT

A first semiconductor chip has a first surface in contact with a first circuit board and a second surface on which a second conductor is provided. A second semiconductor chip has a third surface in contact with a second circuit board and a fourth surface on which a third conductor is provided. A first pillar has a fifth surface in contact with the first circuit board. A second circuit board is in contact with a surface of a second conductor, a surface of a third conductor, and the first pillar. A plurality of insulating pillars extends in a direction connecting the first and second circuit boards and are in contact with the first and second circuit boards. A sealing body surrounds the first and second semiconductor chips, the first pillar, and the insulating pillars, and includes.

### CROSS-REFERENCE TO RELATED APPLICATION

This application is based upon and claims the benefit of priority from Japanese Patent Application No. 2024-160083, filed Sep. 17, 2024, the entire contents of which are incorporated herein by reference.

### FIELD

Embodiments described herein relate generally to semiconductor devices.

### BACKGROUND

Semiconductor devices that handle high voltages are known. Such semiconductor devices include a device that includes a substrate, a semiconductor chip, a resin, and a terminal. Examples of the semiconductor chip include a semiconductor element such as a metal oxide semiconductor field effect transistor (MOSFET). The semiconductor chip is disposed on the substrate. The resin covers the substrate, the semiconductor chip, and the terminal. The terminal is coupled to an electrode of the semiconductor chip via a conductor, and is partially exposed through the resin.

### BRIEF DESCRIPTION OF DRAWINGS

FIG. 1 illustrates an example of an external appearance of a semiconductor device according to a first embodiment.

FIG. 2 illustrates an example of components inside the semiconductor device and electrical coupling of the components of the first embodiment.

FIG. 3 illustrates an example of a cross-sectional structure of the semiconductor device of the first embodiment.

FIG. 4 illustrates an example of a cross-sectional structure of the semiconductor device of the first embodiment.

FIG. 5 is a plan view of the inside of the semiconductor device of the first embodiment.

FIG. 6 illustrates an example of a cross-sectional structure of the semiconductor device of the first embodiment.

FIG. 7 illustrates an example of a cross-sectional structure of the semiconductor device of the first embodiment.

FIG. 8 illustrates an example of a cross-sectional structure of the semiconductor device of the first embodiment.

FIG. 9 illustrates an example of a cross-sectional structure of the semiconductor device of the first embodiment.

FIG. 10 illustrates another example of a cross-sectional structure of the semiconductor device of the first embodiment.

FIG. 11 illustrates heat paths in the semiconductor device of the first embodiment.

FIG. 12 is a schematic plan view of the inside of a semiconductor device according to a first modification of the first embodiment.

FIG. 13 illustrates an example of an appearance of a semiconductor device according to a second modification of the first embodiment.

FIG. 14 illustrates an example of a cross-sectional structure of the semiconductor device according to the second modification of the first embodiment.

FIG. 15 is a plan view of the inside of the semiconductor device according to the second modification of the first embodiment.

FIG. 16 is a plan view of the inside of the semiconductor device according to the second modification of the first embodiment.

### DETAILED DESCRIPTION

In general, according to one embodiment, a semiconductor device includes a first circuit board, a first semiconductor chip, a second conductor, a second semiconductor chip, a third conductor, a first pillar, a second circuit board, a plurality of insulating pillars, and a sealing body. The first circuit board includes an insulating first substrate, and a first conductor that is provided on a surface of the first substrate and includes a plurality of first portions separated from each other. The first semiconductor chip has a first surface and a second surface facing each other. The first surface is in contact with one of the first portions. The second conductor is on the second surface of the first semiconductor chip. The second semiconductor chip has a third surface and a fourth surface facing each other. The third surface is in contact with one of the first portions. The third conductor is on the fourth surface of the second semiconductor chip. The first pillar has a fifth surface and a sixth surface facing each other. The fifth surface is in contact with one of the first portions. The second circuit board includes an insulating second substrate, and a fourth conductor that is provided on a surface of the second substrate and includes a plurality of second portions separated from each other. One of the second portions is in contact with a surface of the second conductor on an opposite side from the first semiconductor chip. One of the second portions is in contact with a surface of the third conductor on an opposite side from the second semiconductor chip. One of the second portions is in contact with the sixth surface of the first pillar. A plurality of insulating pillars extends in a direction in which the first circuit board and the second circuit board are connected. Each of the insulating pillars is in contact with the first circuit board and the second circuit board. The sealing body surrounds the first semiconductor chip, the second semiconductor chip, the first pillar, and the insulating pillars, and includes a surface of the semiconductor device.

Embodiments will now be described with reference to the figures. In order to distinguish components having substantially the same function and configuration in an embodiment or over different embodiments from each other, an additional numeral or letter may be added to the end of each reference numeral or letter.

The figures are schematic, and the relation between the thickness and the area of a plane of a component and the ratio between dimensions of components may differ from those in actuality. The figures may include components which differ in relations and/or ratios of dimensions in different figures.

Hereinafter, embodiments will be described using a three-dimensional orthogonal coordinate system. A direction of an x axis is referred to as an X direction. A direction opposite to the X direction is referred to as a −X direction. A direction of a y axis is referred to as a Y direction. A direction opposite to the Y direction is referred to as a −Y direction. A direction of a z axis is referred to as a Z direction, and up indicates the Z direction. A direction opposite to the Z direction is referred to as a −Z direction, and down indicates the −Z direction.

### 1. First Embodiment

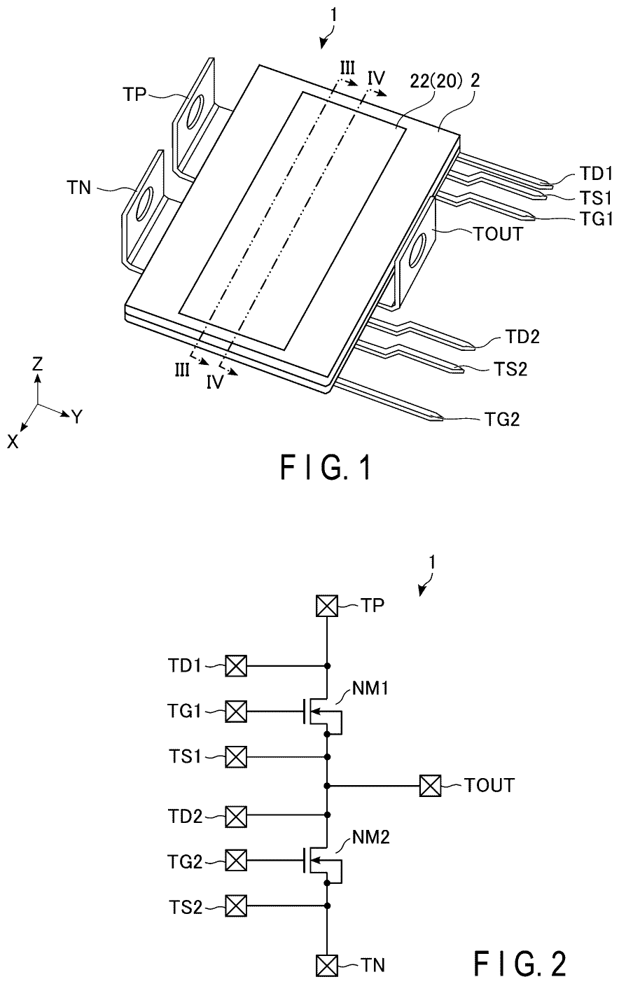

FIG. 1 illustrates an example of an external appearance of a semiconductor device according to a first embodiment. A semiconductor device 1 can function as a semiconductor module forming part of another device.

The semiconductor device 1 includes a sealing body 2, a circuit board 20, and terminals TP, TN, TOUT, TD1, TS1, TG1, TD2, TS2, and TG2.

The sealing body 2 is an insulator that covers the internal structure of the semiconductor device 1. The sealing body 2 extends along the x-y plane. Examples of shapes of the sealing body 2 include a hexahedron, a truncated cone, and a rectangular parallelepiped. A side of these structures may be curved or chamfered. The following description is based on an example in which the sealing body 2 has a rectangular parallelepiped shape. The sealing body 2 has two surfaces that extend along the x-z plane and face each other. The sealing body 2 has two surfaces that extend along the x-y plane and face each other. Of the two surfaces that extend along the x-y plane, the surface located on the +Z direction side is referred to as the upper surface of the sealing body 2 or the semiconductor device 1, and the surface located on the −Z direction side is referred to as the lower surface of the sealing body 2 or the semiconductor device 1. The sealing body 2 covers the internal structure of the semiconductor device 1. In one example, the sealing body 2 contains resin.

The circuit board 20 is a printed circuit board that includes a plate-like shape insulator and a conductor placed on the insulator. A conductor 22 of the circuit board 20 is partially exposed through the upper surface of the sealing body 2.

The terminals TP, TN, TOUT, TD1, TS1, TG1, TD2, TS2, and TG2 are conductors that electrically couple the inside and the outside of the semiconductor device 1.

The terminals TP, TN, and TOUT each have a plate shape. Each of the terminals TP, TN, and TOUT is located inside the sealing body 2 at one end. Each of the terminals TP, TN, and TOUT is located outside the sealing body 2 at the other end. The terminals TP, TN, and TOUT each have an L shape at a portion located outside the sealing body 2. The terminals TP and TN protrude from the surface along the x-z plane of the sealing body 2 and are aligned in the X direction. The terminal TOUT protrudes through a surface of the sealing body 2 which extends over the x-z plane and which faces the surface from which the terminals TP and TN protrude.

Each of the terminals TD1, TS1, TG1, TD2, TS2, and TG2 has a linear shape. Each of the terminals TD1, TS1, TG1, TD2, TS2, and TG2 is located inside the sealing body 2 at one end. Each of the terminals TD1, TS1, TG1, TD2, TS2, and TG2 is located outside the sealing body 2 at the other end. The terminals TD1, TS1, TG1, TD2, TS2, and TG2 protrude from the surface from which the terminal TOUT protrudes. The terminals TD1, TS1, and TG1 are located farther in the −X direction than the terminal TOUT, and are aligned in the +X direction. The terminals TD2, TS2, and TG2 are located farther in the +X direction than the terminal TOUT, and are aligned in the −X direction.

FIG. 2 illustrates an example of components and electrical coupling of the components inside the semiconductor device of the first embodiment. As illustrated in FIG. 2, the semiconductor device 1 includes a half-bridge circuit. More specifically, the semiconductor device 1 includes n-type MOSFETs NM1 and NM2.

The terminals TP and TN are power supply terminals of the semiconductor device 1. While the semiconductor device 1 is being used, the terminal TP receives a positive power supply voltage, and the terminal TN receives a negative power supply voltage.

The terminal TOUT is an output terminal of the semiconductor device 1.

The terminals TD1, TD2, TS1, and TS2 are terminals that are used to monitor operations of the semiconductor device 1.

A transistor NM1 is coupled to the terminal TP and the terminal TD1 at a drain. The transistor NM1 is coupled to the terminal TOUT and the terminal TS1 at a source. The transistor NM1 is coupled to the terminal TG1 at a gate.

A transistor NM2 is coupled to the terminal TOUT and the terminal TD2 at a drain. The transistor NM2 is coupled to the terminal TN and the terminal TS2 at a source. The transistor NM2 is couple to the terminal TG2 at a gate.

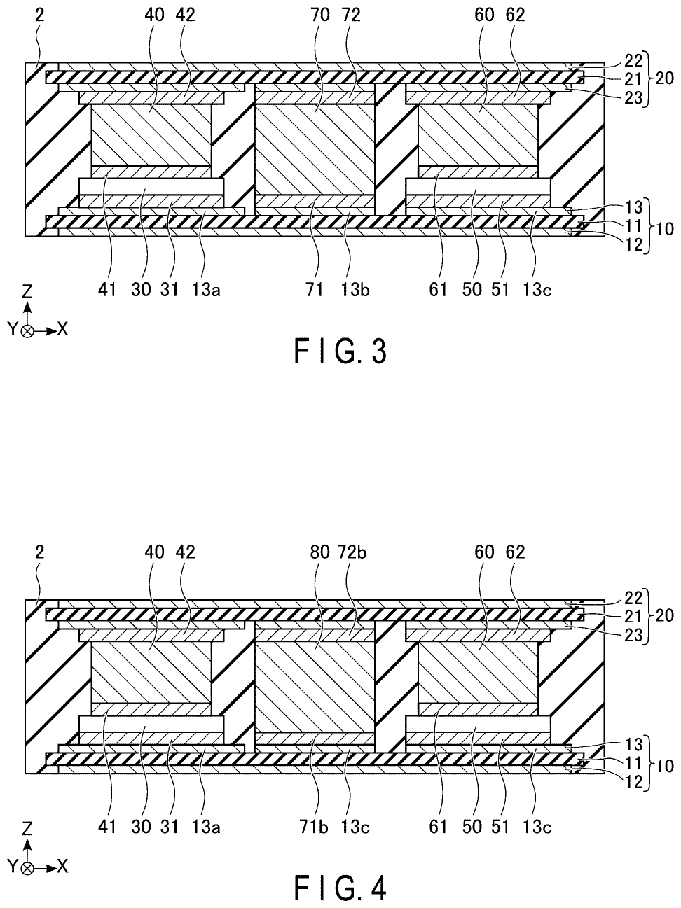

FIG. 3 illustrates an example of a cross-sectional structure of the semiconductor device of the first embodiment. FIG. 3 illustrates a structure extending along the line III-III shown in FIG. 1, and illustrates a structure extending along the x-z plane.

As illustrated in FIG. 3, the semiconductor device 1 further includes circuit boards 10 and 20, semiconductor chips 30 and 50, an inter-board spacer 70, and joining layers 31, 41, 42, 51, 61, 71, and 72.

The circuit board 10 includes a substrate 11, a conductor 12, and a conductor 13. The substrate 11 is an insulating substrate. In one example, the substrate 11 contains ceramics, or is formed with ceramics. The substrate 11 extends along the x-y plane.

The conductor 12 has a plate-like shape. The conductor 12 is provided on the surface (lower surface) of the substrate 11 on the −Z direction side. In one example, the conductor 12 contains copper.

The conductor 13 has a plate-like shape extending along the x-y plane, and has a pattern of a certain shape. The conductor 13 is provided on the surface (upper surface) of the substrate 11 on the +Z direction side. The conductor 13 includes a plurality of parts. Each part of the conductor 13 functions as a circuit pattern, and will be hereinafter referred to as a circuit pattern. Specifically, in one example, the conductor 13 includes circuit patterns 13a, 13b, and 13c. The circuit patterns 13a, 13b, and 13c are separated from one another, and are electrically insulated from one another. In one example, the conductor 13 contains copper.

The circuit board 20 includes a substrate 21, the conductor 22, and a conductor 23. The substrate 21 is an insulating substrate. In one example, the substrate 21 contains ceramics, or is formed with ceramics. The substrate 21 extends along the x-y plane.

The conductor 22 has a plate-like shape. The conductor 22 is provided on the upper surface of the substrate 21 on the +Z direction side. In one example, the conductor 22 contains copper.

The conductor 23 has a plate-like shape extending along the x-y plane, and has a pattern of a certain shape. The conductor 23 is provided on the lower surface of the substrate 21. The conductor 23 includes a plurality of parts. Each part of the conductor 23 functions as a circuit pattern, and will be hereinafter referred to as a circuit pattern. The circuit patterns are separated from one another, and are electrically insulated from one another. In one example, the conductor 23 contains copper.

The joining layer 31 has conductivity, and includes a conductor. The joining layer 31 fixes and electrically couples the semiconductor chip 30 and the circuit pattern 13a. In one example, the joining layer 31 contains solder.

The semiconductor chip 30 is a chip including a semiconductor element. Examples of the semiconductor element include an n-type MOSFET and an insulated gate bipolar transistor (IGBT). The following description is based on an example with a MOSFET, and accordingly, the semiconductor chip 30 includes a gate electrode, a source electrode, and a drain electrode. The semiconductor chip 30 is joined to the upper surface of the circuit pattern 13a by the joining layer 31. The semiconductor chip 30 is in contact with the joining layer 31 at the drain electrode.

The joining layer 41 has conductivity, and includes a conductor. The joining layer 41 fixes and electrically couples the semiconductor chip 30 and a chip spacer 40. In one example, the joining layer 41 contains solder. The joining layer 41 is in contact with the source electrode of the semiconductor chip 30.

The chip spacer 40 has conductivity, and includes a conductor. A lower surface of the chip spacer 40 is in contact with the joining layer 41, and is electrically coupled to the source electrode of the semiconductor chip 30 via the joining layer 41. The chip spacer 40 also functions as a heat-dissipating path for releasing heat generated in the semiconductor chip 30 into the circuit board 20. The chip spacer 40 may be referred to as a pillar.

The joining layer 42 has conductivity, and includes a conductor. The joining layer 42 fixes and electrically couples the chip spacer 40 and a circuit pattern (or a part) of the conductor 23. A lower surface of the joining layer 42 is in contact with the chip spacer 40. An upper surface of the joining layer 42 is in contact with a circuit pattern (or a part) of the conductor 23. In other words, the chip spacer 40 and the circuit pattern (which is a part of the conductor 23) are coupled via the joining layer 42. In one example, the joining layer 42 contains solder.

The joining layer 51 has conductivity, and includes a conductor. The joining layer 51 fixes and electrically couples the semiconductor chip 50 and the circuit pattern 13c. In one example, the joining layer 51 contains solder.

The semiconductor chip 50 is a chip including a semiconductor element. Examples of the semiconductor element include an n-type MOSFET and an IGBT. The following description is based on an example with a MOSFET, and accordingly, the semiconductor chip 50 includes a gate electrode, a source electrode, and a drain electrode. The semiconductor chip 50 is joined to the upper surface of the circuit pattern 13c by the joining layer 51. The semiconductor chip 50 is in contact with the joining layer 51 at the drain electrode.

The joining layer 61 has conductivity, and includes a conductor. The joining layer 61 fixes and electrically couples the semiconductor chip 50 and a chip spacer 60. In one example, the joining layer 61 contains solder. The joining layer 61 is in contact with the source electrode of the semiconductor chip 50.

The chip spacer 60 has conductivity, and includes a conductor. A lower surface of the chip spacer 60 is in contact with the joining layer 61, and is electrically coupled to the source electrode of the semiconductor chip 50 via the joining layer 61. The chip spacer 60 also functions as a heat-dissipating path for releasing heat generated in the semiconductor chip 50 into the circuit board 20. The chip spacer 60 may be referred to as a pillar.

The joining layer 62 has conductivity, and includes a conductor. The joining layer 62 fixes and electrically couples the chip spacer 60 and a circuit pattern of the conductor 23 (or a part) of the conductor 23. A lower surface of the joining layer 62 is in contact with the chip spacer 60. An upper surface of the joining layer 62 is in contact with a circuit pattern (or a part) of the conductor 23. In other words, the chip spacer 60 and the circuit pattern (which is a part of the conductor 23) are coupled via the joining layer 62. In one example, the joining layer 62 contains solder.

The joining layer 71 has conductivity, and includes a conductor. The joining layer 71 fixes and electrically couples the inter-board spacer 70 and the circuit pattern 13b. The lower surface of the joining layer 71 is in contact with the circuit pattern 13b. In one example, the joining layer 71 contains solder.

The inter-board spacer 70 has conductivity, and includes a conductor. The inter-board spacer 70 fixes and electrically couples the circuit pattern 13b and a circuit pattern of the conductor 23 (or a part of the conductor 23). The lower surface of the inter-board spacer 70 is in contact with the joining layer 71. In other words, the circuit pattern 13b and the inter-board spacer 70 are coupled via the joining layer 71. The inter-board spacer 70 is coupled to the circuit pattern 13b via the joining layer 71. The inter-board spacer 70 also functions as a heat-dissipating path for releasing heat generated in the semiconductor chips 30 and 50 into the circuit board 20. In one example, the inter-board spacer 70 has a higher hardness than the hardness of the material of the sealing body 2. In one example, the inter-board spacer 70 contains a set of silicon carbide (SiC) and aluminum (Al).

The joining layer 72 has conductivity, and includes a conductor. The joining layer 72 fixes and electrically couples the inter-board spacer 70 and a circuit pattern of the conductor 23 (or a part) of the conductor 23. A lower surface of the joining layer 72 is in contact with the inter-board spacer 70. An upper surface of the joining layer 72 is in contact with a circuit pattern of the conductor 23 (or a part) of the conductor 23. In other words, the inter-board spacer 70 and the circuit pattern (which is a part of the conductor 23) are coupled via the joining layer 72. In one example, the joining layer 72 contains solder.

FIG. 4 illustrates an example of a cross-sectional structure of the semiconductor device of the first embodiment. FIG. 4 illustrates a structure extending along the line IV-IV defined in FIG. 1, and illustrates a structure extending along the x-z plane.

As illustrated in FIG. 4, the semiconductor device 1 further includes an inter-board spacer 80. The joining layer 71 (71b) fixes and electrically couples the inter-board spacer 80 and the circuit pattern 13c. A lower surface of the joining layer 71b is in contact with the circuit pattern 13c.

The inter-board spacer 80 has conductivity, and includes a conductor. The inter-board spacer 80 fixes and electrically couples the circuit pattern 13c and a circuit pattern of the conductor 23 (or a part) of the conductor 23. A lower surface of the inter-board spacer 80 is in contact with the joining layer 71b. In other words, the circuit pattern 13c and the inter-board spacer 80 are coupled via the joining layer 71b. The inter-board spacer 80 is coupled to the circuit pattern 13c via the joining layer 71b. The inter-board spacer 80 also functions as a heat-dissipating path for releasing heat generated in the semiconductor chips 30 and 50 into the circuit board 20. In one example, the inter-board spacer 80 has a higher hardness than the hardness of the material of the sealing body 2. In one example, the inter-board spacer 80 contains a set of silicon carbide and aluminum.

The joining layer 72 (72b) fixes and electrically couples the inter-board spacer 80 and a circuit pattern of the conductor 23. A lower surface of the joining layer 72b is in contact with the inter-board spacer 80. An upper surface of the joining layer 72b is in contact with a circuit pattern of the conductor 23 (or a part of the conductor 23). In other words, the inter-board spacer 80 and the circuit pattern (which is a part of the conductor 23) are coupled via the joining layer 72b.

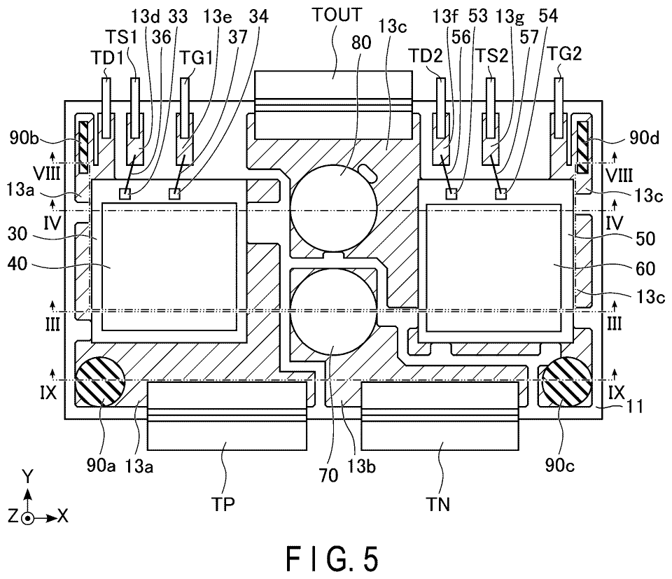

FIG. 5 is a plan view of the inside of the semiconductor device of the first embodiment. FIG. 5 illustrates the inside of the semiconductor device 1 along the x-y plane. The structure shown in FIG. 3 is the cross-sectional structure taken along the line III-III shown in FIG. 5.

In the description related to FIG. 5, “upper”, “upper side”, and “above” refer to the +Z direction, and “lower”, “lower side”, and “below”refer to the −Z direction. Accordingly, in the description related to FIG. 5, the “upper surface” of a component refers to the surface of the component on the +Z direction side, and the “lower surface” of the component refers to the surface of the component on the −Z direction side.

The semiconductor chip 30 and the chip spacer 40 each have a quadrilateral shape. The semiconductor chip 30 has a larger shape than the chip spacer 40. The semiconductor chip 30 further includes electrode pads 33 and 34. The electrode pad 33 is a pad for the source electrode of the semiconductor chip 30. The electrode pad 34 is a pad for the gate electrode of the semiconductor chip 30. The electrode pads 33 and 34 are not covered with the chip spacer 40.

The semiconductor chip 50 and the chip spacer 60 each have a quadrilateral shape. The semiconductor chip 50 has a larger shape than the chip spacer 60. The semiconductor chip 50 further includes electrode pads 53 and 54. The electrode pad 53 is a pad for the drain electrode of the semiconductor chip 50. The electrode pad 54 is a pad for the source electrode of the semiconductor chip 50. The electrode pads 53 and 54 are not covered with the chip spacer 60.

The inter-board spacer 70 has a pillar-like shape. In one example, the inter-board spacer 70 has a columnar or prismatic shape.

The inter-board spacer 80 has a pillar-like shape. In one example, the inter-board spacer 80 has a columnar or prismatic shape.

The circuit pattern 13a spreads over a region below the semiconductor chip 30 (which is on the −Z direction side), a region below the terminal TP, and a region below the terminal TD1. An upper surface of the circuit pattern 13a is in contact with a lower surface of the terminal TP and a lower surface of the terminal TD1.

The circuit pattern 13b spreads over a region below the inter-board spacer 70 and a region below the terminal TN. The circuit pattern 13b faces the circuit pattern 13a with a space in between, below a region between the semiconductor chip 30 and the inter-board spacer 70. The circuit pattern 13b faces the circuit pattern 13a with a space in between, below a region between the terminal TP and the terminal TN. An upper surface of the circuit pattern 13b is in contact with a lower surface of the terminal TN. The circuit pattern 13b overlaps the inter-board spacer 70.

The circuit pattern 13c spreads over a region below the semiconductor chip 50, a region below the terminal TOUT, and a region below the terminal TG2. The circuit pattern 13c is located below a region positioned farther in the +Y direction side than the inter-board spacer 70, and includes a portion facing a portion of the circuit pattern 13b below the inter-board spacer 70 with a space in between. An upper surface of the circuit pattern 13c is in contact with a lower surface of the terminal TOUT and a lower surface of the terminal TG2. The circuit pattern 13c overlaps the inter-board spacer 80.

The conductor 13 further includes circuit patterns 13d, 13e, 13f, and 13g. The circuit patterns 13d, 13e, 13f, and 13g are separated from one another, and are electrically insulated from one another. The circuit patterns 13d, 13e, 13f, and 13g are separated and electrically insulated from any of the circuit patterns 13a, 13b, and 13c.

The circuit pattern 13d faces a portion of the circuit pattern 13a below the terminal TD1 and a portion of the circuit pattern 13a below the semiconductor chip 30, with a space in between. The circuit pattern 13d is located below the terminal TS1. An upper surface of the circuit pattern 13d is in contact with a lower surface of the terminal TS1. The circuit pattern 13d is coupled to the electrode pad 33 by a bonding wire 36.

The circuit pattern 13e is located farther in the +X direction side than the circuit pattern 13d, and faces a portion below the semiconductor chip 30 with a space in between. The circuit pattern 13e is located below the terminal TG1. An upper surface of the circuit pattern 13e is in contact with a lower surface of the terminal TG1. The circuit pattern 13e is connected to the electrode pad 34 by a bonding wire 37.

The circuit pattern 13f faces a portion of the circuit pattern 13c below the terminal TOUT and a portion of the circuit pattern 13c below the semiconductor chip 50, with a space in between. The circuit pattern 13f is located below the terminal TD2. An upper surface of the circuit pattern 13f is in contact with a lower surface of the terminal TD2. The circuit pattern 13f is connected to the electrode pad 53 by a bonding wire 56.

The circuit pattern 13g is located farther in the +X direction side than the circuit pattern 13f, and faces a portion of the circuit pattern 13c below the semiconductor chip 50 with a space in between. The circuit pattern 13g is located below the terminal TS2. An upper surface of the circuit pattern 13g is in contact with a lower surface of the terminal TS2. The circuit pattern 13g is coupled to the electrode pad 54 by a bonding wire 57.

The shape and the layout of the circuit patterns 13a, 13b, 13c, 13d, 13e, 13f, and 13g shown in FIG. 5 are merely an example. The circuit patterns 13a, 13b, 13c, 13d, 13e, 13f, and 13g may have any shape and layout, as long as a circuit intended to form the semiconductor device 1 is obtained, including the circuit illustrated as an example in FIG. 2.

The semiconductor device 1 further includes an inter-board spacer 80 and insulators 90 (90a, 90b, 90c, and 90d).

The insulators 90a and 90b are located around the semiconductor chip 30. In one example, the insulators 90a and 90b are provided at such positions that the region surrounded by the insulators 90a and 90b and the inter-board spacers 70 and 80 surrounds the semiconductor chip 30 and does not overlap the semiconductor chip 30, the terminals TP, TD1, TS1, and TG1, and the bonding wires 36 and 37. In this case, the respective directions from the semiconductor chip 30 toward the insulators 90a and 90b and the inter-board spacers 70 and 80 are different from one another. That is, the four directions from the semiconductor chip 30 toward the insulators 90a and 90b and the inter-board spacers 70 and 80 are different from one another. In one example, the insulators 90a and 90b are disposed so that the semiconductor chip 30 is accommodated in the region surrounded by straight lines connecting each two adjacent components among the insulators 90a and 90b and the inter-board spacers 70 and 80. The insulators 90a and 90b are only required to be located around the semiconductor chip 30, and the region surrounded by the insulators 90a and 90b and the inter-board spacers 70 and 80 does not necessarily thoroughly surround the semiconductor chip 30. In one example, the insulators 90a and 90b are located in the vicinities of corners of the substrate 11. The insulators 90a and 90b each have such a shape and dimensions that the insulators 90a and 90b can be provided at such positions that the region surrounded by the insulators 90a and 90b and the inter-board spacers 70 and 80 surrounds the semiconductor chip 30 and does not overlap the semiconductor chip 30, the terminals TP, TD1, TS1, and TG1, and the bonding wires 36 and 37. As described later, the insulators 90a and 90b contribute to maintaining the structure of the semiconductor device 1, and function as heat-dissipating paths. These advantages are greater in a case where the insulators 90a and 90b each have a larger volume. In the following, examples of the shapes, the layout, and the dimensions of the insulators 90a and 90b are described. Each of the insulators 90a and 90b may be referred to as a pillar.

In one example, the insulator 90a is located in the vicinity of the corner formed by the end of the substrate 11 on the −X direction side and the end of the substrate 11 on the −Y direction side (this corner may be hereinafter referred to as the lower left corner). In one example, the entire or part of the insulator 90a overlaps the conductor 13 in the vicinity of the lower left corner of the substrate 11, and, in one example, overlaps the circuit pattern 13a. In one example, the insulator 90a has a pillar-like shape extending along the z-axis, and has a columnar or prismatic shape. The insulator 90a extends to the vicinities of the semiconductor chip 30 and the terminal TP. The insulator 90a may have a wall-like shape, extending along the x-y plane. In this case, the insulator 90a may be referred to as a wall. The insulator 90a may also be referred to as a pillar.

In one example, the insulator 90b is located in the vicinity of the corner formed by the end of the substrate 11 on the −X direction side and the end of the substrate 11 on the +Y direction side (this corner may be hereinafter referred to as the upper left corner). In one example, the entire or part of the insulator 90b overlaps the conductor 13 in the vicinity of the upper left corner of the substrate 11, and, in one example, overlaps the circuit pattern 13a. In one example, based on the fact that the terminal TD1 is located in the vicinity of the upper left corner of the substrate 11, the insulator 90b has a shape extending along the region between the terminal TD1 and the end of the substrate 11. In one example, the insulator 90b extends along the y-axis. The insulator 90b extends along the z-axis.

The insulators 90c and 90d are located around the semiconductor chip 50. In one example, the insulators 90c and 90d are provided at such positions that the region surrounded by the insulators 90c and 90d and the inter-board spacers 70 and 80 surrounds the semiconductor chip 50 and does not overlap the semiconductor chip 50, the terminals TN, TD2, TS2, and TG2, and the bonding wires 56 and 57. In other words, the respective directions from the semiconductor chip 50 toward the insulators 90c and 90d and the inter-board spacers 70 and 80 are different from one another. That is, the four directions from the semiconductor chip 50 toward the insulators 90c and 90d and the inter-board spacers 70 and 80 are different from one another. In one example, the insulators 90c and 90d are disposed so that the semiconductor chip 50 is accommodated in the region surrounded by straight lines connecting each two adjacent components among the insulators 90c and 90d and the inter-board spacers 70 and 80. The insulators 90c and 90d are only required to be located around the semiconductor chip 50, and the region surrounded by the insulators 90c and 90d and the inter-board spacers 70 and 80 does not necessarily thoroughly surround the semiconductor chip 50. In one example, the insulators 90c and 90d are located in the vicinities of corners of the substrate 11. The insulators 90c and 90d each have such a shape and dimensions that the insulators 90c and 90d can be provided at such positions that the region surrounded by the insulators 90c and 90d and the inter-board spacers 70 and 80 surrounds the semiconductor chip 50 and does not overlap the semiconductor chip 50, the terminals TN, TD2, TS2, and TG2, and the bonding wires 56 and 57. As described later, the insulators 90c and 90d contribute to maintaining the structure of the semiconductor device 1, and function as heat-dissipating paths. These advantages are greater in a case where the insulators 90c and 90d each have a larger volume. In the following, examples of the shapes, the layout, and the dimensions of the insulators 90c and 90d are described. The insulators 90c and 90d may be referred to as walls or pillars.

In one example, the insulator 90c is located in the vicinity of the corner formed by the end of the substrate 11 on the +X direction side and the end of the substrate 11 on the −Y direction side (this corner may be hereinafter referred to as the lower right corner). In one example, the entire or part of the insulator 90c overlaps the conductor 13 in the vicinity of the lower right corner of the substrate 11, and, in one example, overlaps the circuit pattern 13a. In one example, the insulator 90c has a pillar-like shape extending along the z-axis, and has a columnar or prismatic shape. The insulator 90c extends to the vicinities of the semiconductor chip 30 and the terminal TN. The insulator 90c may have a wall-like shape, extending along the x-y plane.

In one example, the insulator 90d is located in the vicinity of the corner formed by the end of the substrate 11 on the +X direction side and the end of the substrate 11 on the +Y direction side (this corner may be hereinafter referred to as the upper right corner). In one example, the entire or part of the insulator 90d overlaps the conductor 13 in the vicinity of the upper right corner of the substrate 11, and, in one example, overlaps the circuit pattern 13c. In one example, based on the fact that the terminal TG2 is located in the vicinity of the upper right corner of the substrate 11, the insulator 90d has a shape extending along the region between the terminal TG2 and the end of the substrate 11. In one example, the insulator 90d extends along the y-axis. The insulator 90d extends along the z-axis.

The insulators 90a, 90b, 90c, and 90d contain a material different from the material of the sealing body 2. In one example, the insulators 90a, 90b, 90c, and 90d contain ceramics. Examples of the ceramics include alumina.

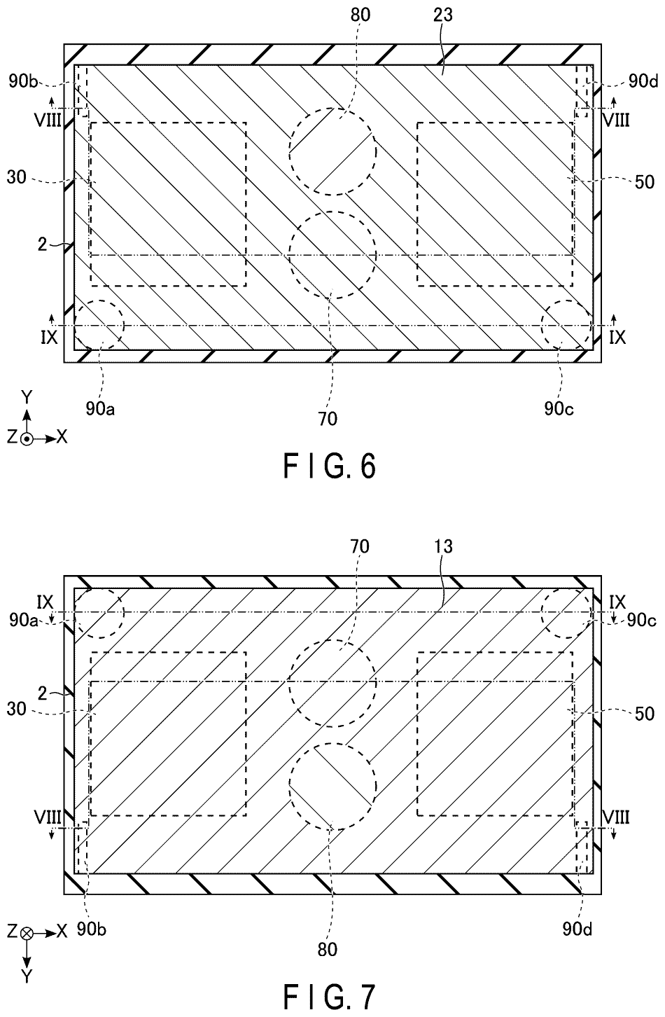

FIG. 6 is a cross-sectional view of the semiconductor device of the first embodiment. Specifically, FIG. 6 shows a cross-section along the x-y plane, and illustrates a structure of the layer in which the conductor 23 is located.

As illustrated in FIG. 6, the conductor 23 overlaps the semiconductor chips 30 and 50, the inter-board spacers 70 and 80, and the insulators 90a, 90b, 90c, and 90d. In one example, the entire portion of each of the insulators 90a, 90b, 90c, and 90d overlaps the conductor 23.

FIG. 7 is a cross-sectional view of the semiconductor device of the first embodiment. Specifically, FIG. 7 shows a cross-section along the x-y plane, and illustrates a structure of the layer in which the conductor 13 is located.

As illustrated in FIG. 7, the conductor 13 overlaps the semiconductor chips 30 and 50, the inter-board spacers 70 and 80, and the insulators 90a, 90b, 90c, and 90d. In one example, the entire portion of each of the insulators 90a, 90b, 90c, and 90d overlaps the conductor 13.

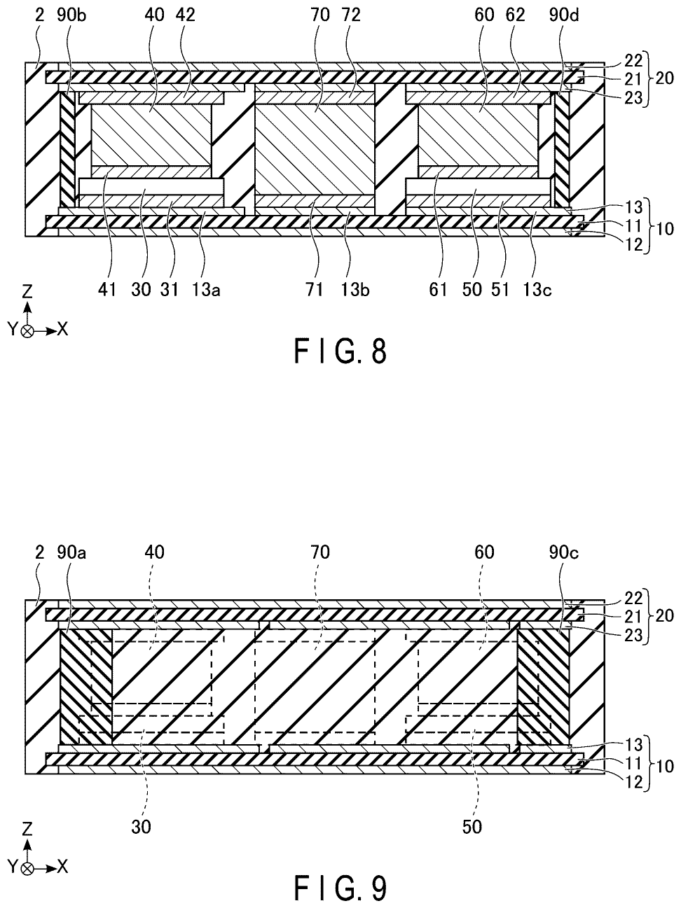

FIGS. 8 and 9 illustrate an example of a cross-sectional structure of the semiconductor device of the first embodiment. FIG. 8 shows a cross-section taken along the line VIII-VIII defined in FIGS. 5, 6, and 7, and shows a cross-section taken along the x-z plane. FIG. 9 shows a cross-section taken along the line IX-IX shown in FIGS. 5, 6, and 7, and shows a cross-section taken along the x-z plane.

As illustrated in FIGS. 8 and 9, lower surfaces of the insulators 90a, 90b, 90c, and 90d are in contact with an upper surface of the conductor 13. The insulators 90a, 90b, 90c, and 90d may be located outside the conductor 13 and/or above a region between circuit patterns of the conductor 13 (which is a region between parts of the conductor 13), and thus, are not necessarily in contact with the conductor 13 at some portions of the lower surfaces.

Upper surfaces of the insulators 90a, 90b, 90c, and 90d are in contact with a lower surface of the conductor 23. The insulators 90a, 90b, 90c, and 90d may be located outside the conductor 23 and (or) below a region between circuit patterns of the conductor 23 (which is a region between parts of the conductor 23), and thus, are not necessarily in contact with the conductor 23 at some portions of the upper surfaces.

Side surfaces of the insulators 90a, 90b, 90c, and 90d are covered with the sealing body 2.

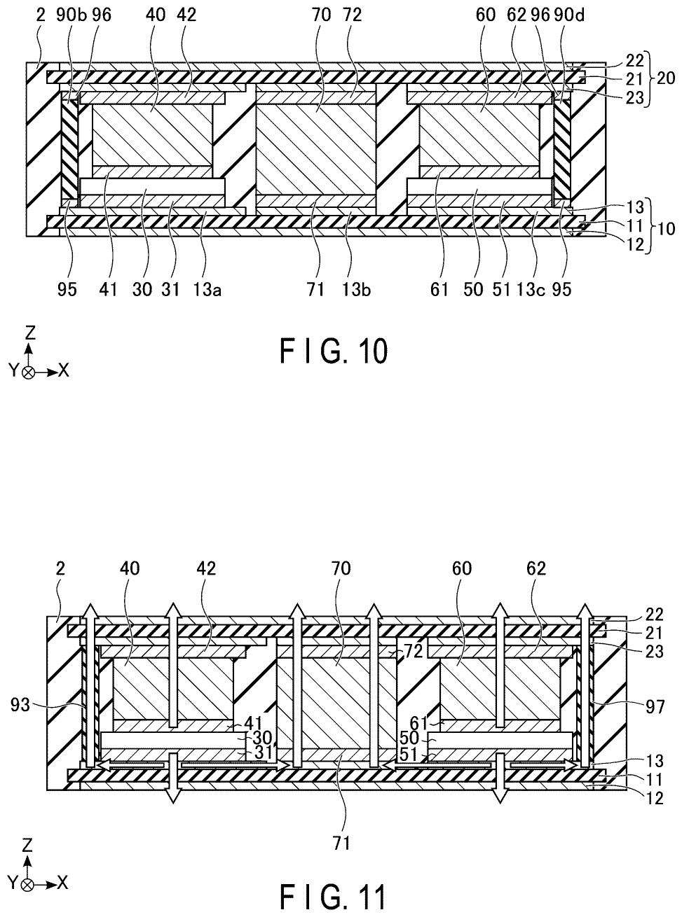

As illustrated in FIG. 10, the insulators 90a, 90b, 90c, and 90d may be provided on the conductor 13 via a solder 95. Alternatively, or in addition to that, a solder 96 may be provided between the insulators 90a, 90b, 90c, and 90d and the conductor 13. FIG. 10 illustrates the same region as that in FIG. 8. In the case of the structure illustrated in FIG. 10, the insulators 90a, 90b, 90c, and 90d may include a copper layer between them and the solder 95.

According to the first embodiment, a semiconductor device having high reliability and high strength is provided as described below.

A semiconductor device like the semiconductor device 1 can be sandwiched by a cooler from the upper surface and the lower surface in a device including the semiconductor device. The semiconductor device includes a sealing body. However, the strength of the sealing body is not so high, and, in some cases, the sealing body does not have a strength sufficiently high to withstand the pressure from the cooler. According to the first embodiment, the semiconductor device 1 includes the inter-board spacers 70 and 80 and the insulators 90 in contact with the circuit boards 10 and 20, and the inter-board spacers 70 and 80 and the insulators 90 are disposed so as to surround the semiconductor chips 30 and 50. Accordingly, the semiconductor device 1 has high strength in the region between the semiconductor device 1 and the circuit boards 10 and 20, and, in particular, the pressure applied from the upper surface and the lower surface of the semiconductor device 1 in the region surrounded by the inter-board spacers 70 and 80 and the insulators 90 is alleviated. Thus, the pressure to be applied to the semiconductor chips 30 and 50 located in the region surrounded by the inter-board spacer 70 and the insulators 90 is reduced, and damage to and (or) deformation of the semiconductor chips 30 and 50 are reduced.

Also, in a semiconductor device like the semiconductor device 1, heat generated in the semiconductor chips is transferred to a lower circuit board and an upper circuit board, and is dissipated therein. Since the upper circuit board is in contact with the semiconductor chips via the spacers while the lower circuit board is in direct contact with the semiconductor chips, a larger amount of heat is released from the lower circuit board than from the upper circuit board. Although the heat generated in lower portions of the semiconductor chips is guided to the upper circuit board by the inter-board spacers, the heat distribution inside the semiconductor device may still be uneven. This leads to a decrease in reliability of the semiconductor device. According to the first embodiment, the semiconductor device 1 includes the insulators 90 in contact with the circuit boards 10 and 20. As indicated by arrows in FIG. 11, the insulators 90 guide the heat generated in the semiconductor chips 30 and 50 to the circuit board 20 via the insulators 90 in the same manner as the manner in which the heat generated in the semiconductor chips 30 and 50 is guided to the circuit board 20 via the inter-board spacer 70. Because of this, a larger amount of the heat generated in the semiconductor chips 30 and 50 is guided to the circuit board 20, and accordingly, the unevenness in the heat distribution inside the semiconductor device 1 is reduced. Thus, the semiconductor device 1 has high reliability.

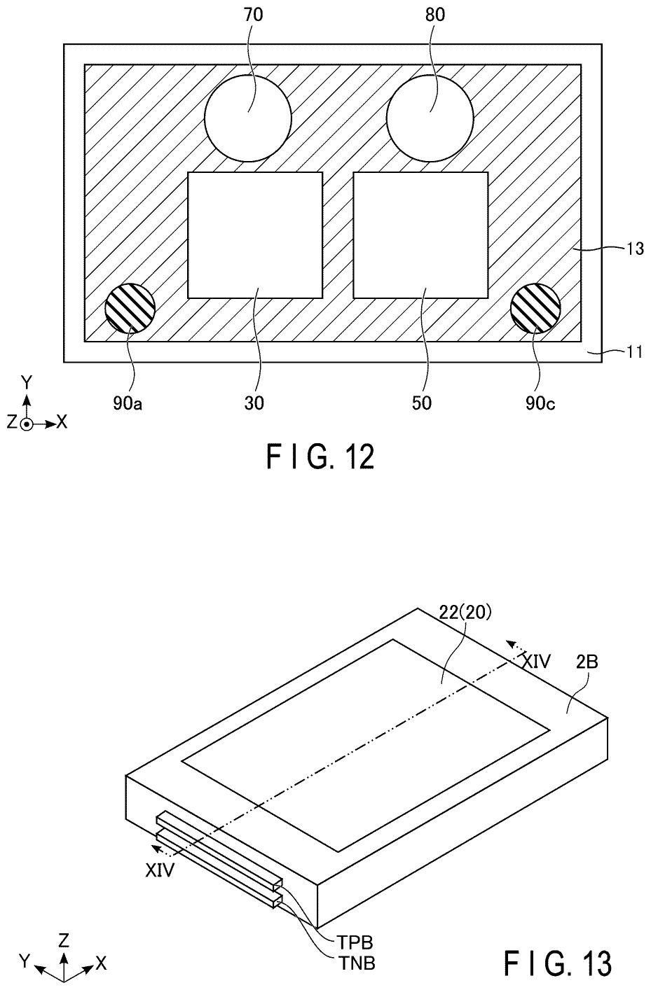

As described above, the insulators 90, together with the inter-board spacers 70 and 80, are only required to surround the semiconductor chips 30 and 50. Therefore, the insulators 90 can be disposed at various positions, depending on the layout of the semiconductor chips 30 and 50 and the inter-board spacers 70 and 80. FIG. 12 is a schematic plan view of the inside of a semiconductor device according to a first modification of the first embodiment. FIG. 12 does not illustrate details of the circuit patterns of the conductor 13.

As illustrated in FIG. 12, the semiconductor chip 30 and the inter-board spacer 70 are aligned in the +Y direction. The semiconductor chip 50 and the inter-board spacer 80 are aligned in the +Y direction. Based on the layout of the semiconductor chips 30 and 50 and the inter-board spacers 70 and 80, the insulator 90a is located in the vicinity of the lower left corner of the substrate 11, and the insulator 90c is located in the vicinity of the lower right corner of the substrate 11.

The semiconductor chips 30 and 50 may be aligned in the +Z direction. FIG. 13 illustrates such an example, and illustrates an example of an appearance of a semiconductor device according to a second modification of the first embodiment. As illustrated in FIG. 13, terminals TNB and TPB protrude from the same surface of a sealing body 2B. The terminals TNB and TPB are aligned in the +Z direction. A portion of the terminal TNB located outside the sealing body 2B has a plate-like shape extending along the x-y plane. A portion of the terminal TPB located outside the sealing body 2B has a plate-like shape extending along the x-y plane.

Terminals TT1, TT2, and TOUTB (not shown) protrude from a surface of the sealing body 2B, the surface being on the opposite side from the surface from which the terminals TNB and TPB protrude.

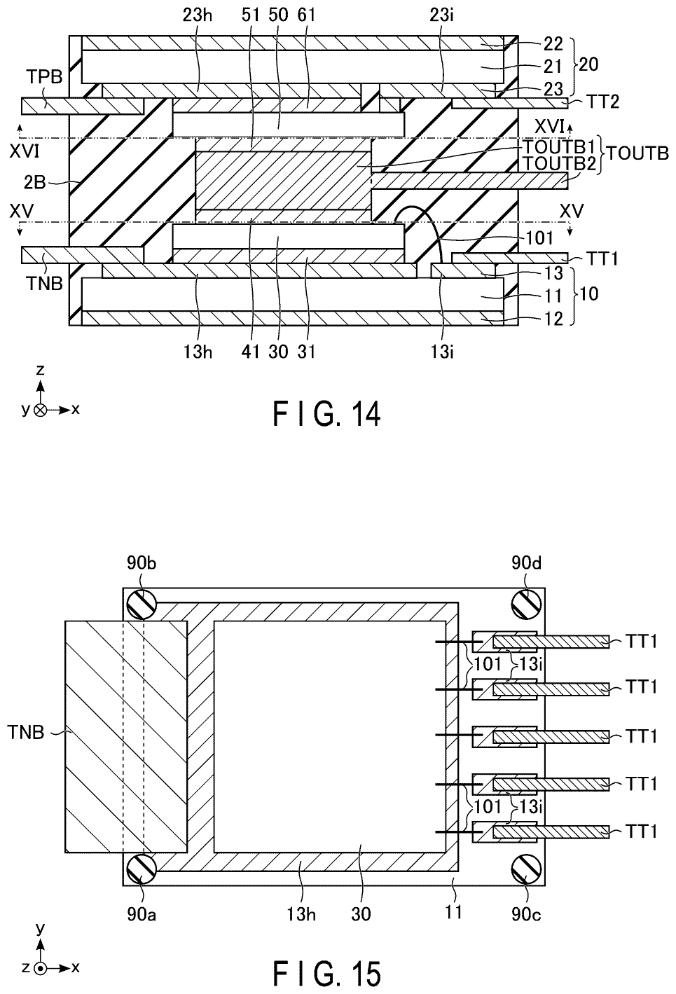

FIG. 14 illustrates an example of a cross-sectional structure of the semiconductor device according to the second modification of the first embodiment. FIG. 14 illustrates a cross-section taken along the line XIV-XIV defined in FIG. 13, and illustrates a cross-section taken along the x-z plane.

As illustrated in FIG. 14, the conductor 13 includes portions (which are circuit patterns) 13h and 13i. The terminal TNB is provided on an upper surface of the circuit pattern 13h. An upper surface of the circuit pattern 13i is in contact with the terminal TT1. The terminal TT1 protrudes from the surface of the sealing body 2B on the +X direction side, the surface extending along the y-z plane.

The semiconductor chip 30 is coupled to the circuit pattern 13i via a bonding wire 101 at an electrode (not shown) on an upper surface.

A lower surface of the terminal TOUTB is in contact with an upper surface of the semiconductor chip 30. The terminal TOUTB includes a first portion TOUTB1 in contact with the semiconductor chip 30, and a second portion TOUTB2. The second portion TOUTB2 is continuous with the first portion TOUTB1, and is located farther in the +X direction side than the first portion TOUTB1. The second portion TOUTB2 protrudes from the surface of the sealing body 2B on the +X direction side, the surface extending along the y-z plane. The second portion TOUTB2 is located farther in the +Z direction side than the terminal TT1.

The joining layer 51 is provided on an upper surface of the second portion TOUTB2 of the terminal TOUTB.

The circuit board 20 is provided on an upper surface of the joining layer 61. The conductor 23 includes portions (circuit patterns) 23h and 23i. The terminal TPB is provided on a lower surface of the circuit pattern 23h. A lower surface of the circuit pattern 23i is in contact with an upper surface of an electrode (not shown) of the semiconductor chip 50 via the joining layer 61, and an upper surface of the terminal TT2. The terminal TT2 protrudes from the surface of the sealing body 2B on the +X direction side, the surface extending along the y-z plane. The terminal TT2 is located farther in the +Z direction side than the second portion TOUTB2 of the terminal TOUTB.

FIG. 15 is a plan view of the inside of the semiconductor device according to the second modification of the first embodiment. FIG. 15 illustrates a structure in a case where the inside of the semiconductor device 1 is viewed from the +Z direction, and illustrates a structure taken along the line XV −XV defined in FIG. 14. FIG. 15 illustrates a region between the substrate 11 and the semiconductor chip 30.

As illustrated in FIG. 15, the terminal TNB overlaps the circuit pattern 13h at a portion including the end on the +X direction side. The entire semiconductor chip 30 overlaps the circuit pattern 13h. The semiconductor chip 30 is located farther in the +X direction side than the terminal TNB.

The circuit patterns 13i are located farther in the +X direction side than the circuit pattern 13h. The circuit patterns 13i extend in the +X direction, and are arranged at intervals in the +Y direction. Each circuit pattern 13i is in contact with one bonding wire 101. Each circuit pattern 13i overlaps one terminal TT1, and is in contact with one terminal TT1. Each terminal TT1 is one of the terminals TD1, TG1, and TS1.

The insulators 90a, 90b, 90c, and 90d surround the semiconductor chip 30. In one example, the insulator 90a is located in the vicinity of the lower left corner of the substrate 11. In one example, the insulator 90b is located in the vicinity of the upper left corner of the substrate 11. In one example, the insulator 90c is located in the vicinity of the lower right corner of the substrate 11. In one example, the insulator 90d is located in the vicinity of the upper right corner of the substrate 11. The entire or part of lower surface of each of the insulators 90a, 90b, 90c, and 90d is in contact with an upper surface of the substrate 11 and/(or an upper surface of the conductor 13.

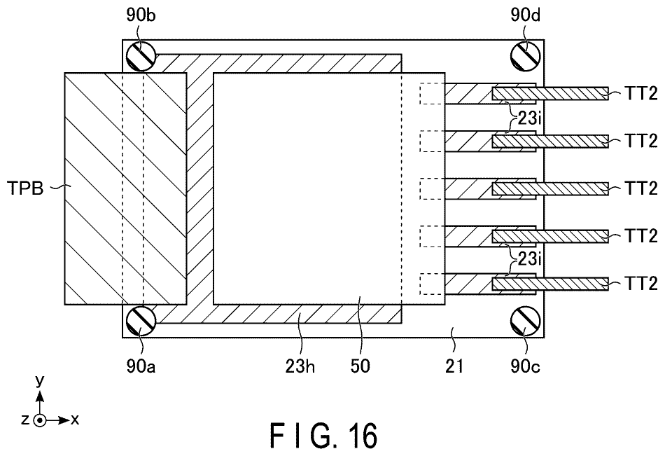

FIG. 16 is a plan view of the inside of the semiconductor device according to the second modification of the first embodiment. FIG. 16 illustrates a structure in a case where the inside of the semiconductor device 1 is viewed from the −Z direction, and illustrates a structure taken along the line XVI −XVI defined in FIG. 14. FIG. 16 illustrates the region between the semiconductor chip 50 and the substrate 21.

As illustrated in FIG. 16, the terminal TPB overlaps the circuit pattern 23h at a portion including the end on the +X direction side. The semiconductor chip 50 overlaps the circuit pattern 23h at a portion including the end on the −X direction side. The semiconductor chip 50 is located farther in the +X direction side than the terminal TPB.

The circuit patterns 23i are located farther in the +X direction side than the circuit pattern 23h. The circuit patterns 23i extend in the +X direction, and are arranged at intervals in the +Y direction. Each circuit pattern 23i overlaps the semiconductor chip 50 at a portion including the end on the −X direction side. Each circuit pattern 23i overlaps one terminal TT2, and is in contact with one terminal TT2. Each terminal TT2 is one of the terminals TD2, TG2, and TS2.

The insulators 90a, 90b, 90c, and 90d surround the semiconductor chip 50. The entire or part of upper surface of each of the insulators 90a, 90b, 90c, and 90d is in contact with a lower surface of the substrate 21 or a lower surface of the conductor 23.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first circuit board including an insulating first substrate, and a first conductor that is provided on a surface of the first substrate and includes a plurality of first portions separated from each other;
a first semiconductor chip having a first surface and a second surface facing each other, the first surface being in contact with one of the first portions;
a second conductor on the second surface of the first semiconductor chip;
a second semiconductor chip having a third surface and a fourth surface facing each other, the third surface being in contact with one of the first portions;
a third conductor on the fourth surface of the second semiconductor chip;
a first pillar having a fifth surface and a sixth surface facing each other, the fifth surface being in contact with one of the first portions;
a second circuit board including an insulating second substrate, and a fourth conductor that is provided on a surface of the second substrate and includes a plurality of second portions separated from each other, one of the second portions being in contact with a surface of the second conductor on an opposite side from the first semiconductor chip, one of the second portions being in contact with a surface of the third conductor on an opposite side from the second semiconductor chip, one of the second portions being in contact with the sixth surface of the first pillar;
a plurality of insulating pillars extending in a direction in which the first circuit board and the second circuit board are connected, each of the insulating pillars being in contact with the first circuit board and the second circuit board; and
a sealing body that surrounds the first semiconductor chip, the second semiconductor chip, the first pillar, and the insulating pillars, and includes a surface of the semiconductor device.

2. The semiconductor device according to claim 1, wherein
the first pillar and a first plurality of insulating pillars among the insulating pillars are located around the first semiconductor chip, and
the first pillar and a second plurality of insulating pillars among the insulating pillars are located around the second semiconductor chip.

3. The semiconductor device according to claim 2, wherein
a set of the first pillar and the first plurality of insulating pillars surround the first semiconductor chip, and
a set of the first pillar and the second plurality of insulating pillars surround the second semiconductor chip.

4. The semiconductor device according to claim 3, wherein
the first pillar is located between the first semiconductor chip and the second semiconductor chip.

5. The semiconductor device according to claim 1, further comprising
a second pillar having a seventh surface and an eighth surface facing each other, the seventh surface being in contact with one of the first portions, the eighth surface being in contact with one of the second portions, wherein
the first pillar, the second pillar, and a first plurality of insulating pillars among the insulating pillars are located around the first semiconductor chip, and
the first pillar, the second pillar, and a second plurality of insulating pillars among the insulating pillars are located around the second semiconductor chip.

6. The semiconductor device according to claim 5, wherein
a set of the first pillar, the second pillar, and the first plurality of insulating pillars surround the first semiconductor chip, and
a set of the first pillar, the second pillar, and the second plurality of insulating pillars surround the second semiconductor chip.

7. The semiconductor device according to claim 6, wherein
the first pillar and the second pillar are located between the first semiconductor chip and the second semiconductor chip.

8. The semiconductor device according to claim 2, wherein
the first plurality of insulating pillars includes at least a first insulating pillar and a second insulating pillar, and
the second plurality of insulating pillars includes at least a third insulating pillar and a fourth insulating pillar.

9. The semiconductor device according to claim 5, wherein
the first plurality of insulating pillars includes at least a first insulating pillar and a second insulating pillar, and
the second plurality of insulating pillars includes at least a third insulating pillar and a fourth insulating pillar.

10. The semiconductor device according to claim 1, wherein
the insulating pillars and the sealing body contain different materials.

11. The semiconductor device according to claim 2, wherein
the insulating pillars and the sealing body contain different materials.

12. The semiconductor device according to claim 5, wherein
the insulating pillars and the sealing body contain different materials.

13. A semiconductor device comprising:
a first circuit board including an insulating first substrate, and a first conductor that is provided on a surface of the first substrate and includes a plurality of first portions separated from each other;
a first semiconductor chip having a first surface and a second surface facing each other, the first surface being in contact with one of the first portions;
a second circuit board including an insulating second substrate, and a second conductor that is provided on a surface of the second substrate and includes a plurality of second portions separated from each other;
a second semiconductor chip having a third surface and a fourth surface facing each other, the fourth surface being in contact with one of the second portions;
a third conductor in contact with the second surface of the first semiconductor chip and the third surface of the second semiconductor chip;
a plurality of insulating pillars extending in a direction in which the first circuit board and the second circuit board are connected, each of the insulating pillars being in contact with the first circuit board and the second circuit board; and
a sealing body that surrounds the first semiconductor chip, the second semiconductor chip, and the insulating pillars, and includes a surface of the semiconductor device.
